(19) United States
(12) Patent Application Publication
(10) Pub. No.: US 2015/0091633 A1
(43) Pub. Date: Apr. 2, 2015

(54) DESIGN METHOD AND DESIGN DEVICE

(71) Applicant: FUJITSU SEMICONDUCTOR LIMITED, Yokohama-shi (JP)

(72) Inventors: Atsushi TSUCHIYA, Akiruno (JP); Seiji GOTO, Kunitachi (JP); Kimihiro SAWADA, Akiruno (JP)

(21) Appl. No.: 14/494,921

(22) Filed: Sep. 24, 2014

(30) Foreign Application Priority Data
Sep. 27, 2013 (JP) 2013-202014

(51) Int. Cl. G06F 17/50; H03K 17/56

(52) U.S. Cl. CPC G06F 17/5072; H03K 17/56
USPC 327/365; 716/120

(57) ABSTRACT

A design method is executed by a computer. The design method includes grouping logical modules in each of power domains arranged on a chip; provisionally arranging regular cells in each of logical module groups formed by the grouping; and arranging power switches around each of the logical module groups.

### CROSS-REFERENCE TO RELATED APPLICATION

This patent application is based upon and claims the benefit of priority of the prior Japanese Patent Application No. 2013-202014 filed on Sep. 27, 2013, the entire contents of which are incorporated herein by reference.

### FIELD

The embodiments discussed herein are related to the power gating design of a chip.

### BACKGROUND

In recent years, a power gating for reducing the power consumption of a chip has been installed in a chip.

For example, there is known a semiconductor integrated circuit provided with cell areas in which a plurality of core cells are arranged, and power switches disposed so as to correspond to the cell areas. Furthermore, a plurality of power cutoff areas are formed in units of the core cells, and it is possible to cut off the power in each of the power cutoff areas.

Furthermore, there is proposed a semiconductor device in which core areas, which are formed on a semiconductor chip, are separated into a plurality of function blocks. At the boundaries of the separated function blocks, a plurality of power switches are arranged, which implement control for supplying or stopping supplying a reference potential to the respective function blocks. There is also proposed a semiconductor integrated circuit in which switch cells are disposed along all four surrounding sides of a circuit block. The switch cell includes two voltage cell lines connected to an internal voltage line, a control cell line connected to a switch control line, and a transistor.

Patent Document 1: International Publication Pamphlet No. 2006/114875

Patent Document 2: Japanese Laid-Open Patent Publication No. 2008-251835

Patent Document 3: Japanese Laid-Open Patent Publication No. 2009-170707

As a technology for reducing power consumption, in on-chip power gating design in which a power switch (hereinafter, “PSW”) is applied, there is a ring type (macro type) PSW and a column type (standard cell type) PSW. The tradeoffs of these two types are as follows.
IR drop in case of peripheral I/O
The IR drop is uniform in the chip in both types.
IR drop in case of area I/O
In the case of the ring type PSW, the power is supplied via the PSWs along the outer periphery of the power domain (PD), and therefore there is a disadvantage in that the IR drop is large at the center part of the PD.

Meanwhile, in the case of the column type PSW, it is possible to supply power in the shortest area from the power supply bump disposed in an area inside the PD, and therefore an IR drop hardly occurs.
Timing convergence
The timing convergence properties are high in the ring type PSW. However, in the column type PSW, there may be cases were the cells are hampered from being arranged in an optimum manner because the PSW is arranged inside the PD, and therefore the timing convergence properties are not as high as the case of the ring type PSW.

However, in a design using area I/O, it is mainstream to use the column type PSW.

### SUMMARY

According to an aspect of the embodiments, a design method is executed by a computer. The design method includes grouping logical modules in each of power domains arranged on a chip; provisionally arranging regular cells in each of logical module groups formed by the grouping; and arranging power switches around each of the logical module groups.

The object and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 illustrates a configuration example of power gating;

FIGS. 2A and 2B illustrate a typical arrangement example of a PSW;

FIG. 3 is a diagram for describing the features of a ring type PSW and a column type PSW;

FIG. 4 illustrates an example where the timing convergence is degraded;

FIG. 5 illustrates an example of an arrangement result of the column type PSWs according to the an embodiment;

FIG. 6 illustrates an example of an arrangement region;

FIG. 7 illustrates a hardware configuration of a design device;

FIG. 8 illustrates an example of a functional configuration of the design device;

FIG. 9 illustrates a configuration example of a net list;

FIG. 10 illustrates an example of a process of determining the arrangement positions of power domains performed by a floor plan unit;

FIG. 11 is a flowchart for describing a grouping process;

FIG. 12 schematically illustrates an example of a result of the grouping process;

FIG. 13 is for describing the relationship between the arrangement intervals of power supply bumps and the arrangement area of a logical module group;

FIG. 14 is for describing a provisional arrangement process;

FIGS. 15A and 15B are for describing an example of a result of the provisional arrangement process;

FIG. 16 is a flowchart of a provisional arrangement process;

FIG. 17 is a flowchart of a PSW arrangement process;

FIG. 18 illustrates an example of a PSW arrangement process performed by a PSW arrangement unit;

FIG. 19 is a flowchart of an arrangement region setting process; and

FIG. 20 illustrates an example of data stored in physical information.

### DESCRIPTION OF EMBODIMENTS

Preferred embodiments of the present invention will be explained with reference to accompanying drawings.

Power gating is a technology for reducing the leakage current by cutting off the power supply to a circuit that is temporarily not operating. The method of implementing power control inside a chip is referred to as on-chip power gating.

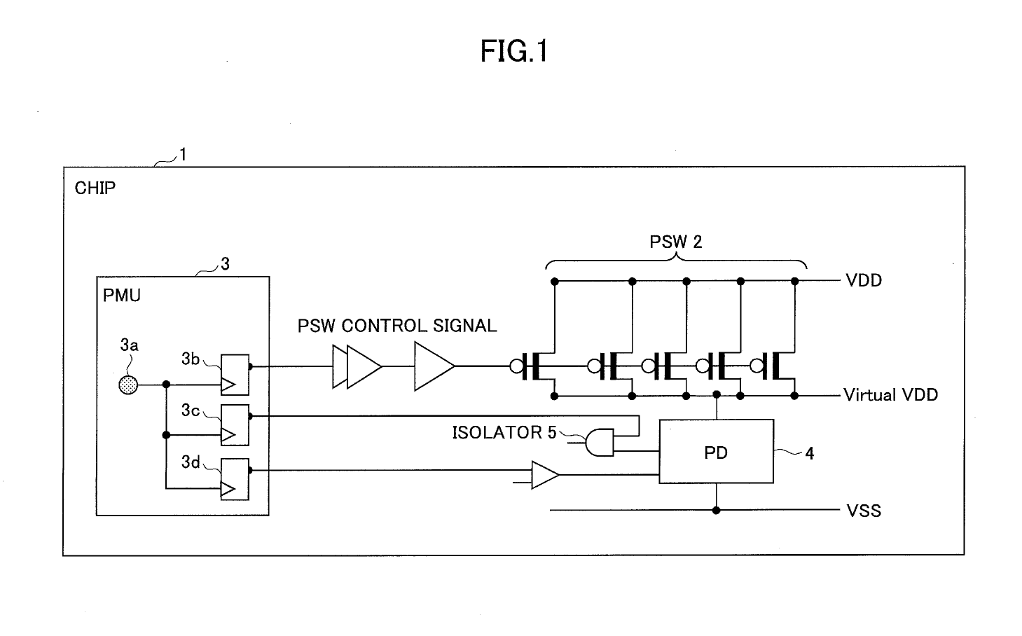

FIG. 1 illustrates a configuration example of power gating. A chip 1 illustrated in FIG. 1 includes a PMU (Power Management Unit) 3, a PSW (Power SWitch) 2, a PD (Power Domain) 4, and an isolator 5. There may be a plurality of the PDs 4.

The PMU 3 is a logical circuit for implementing power control, and includes a clock supply source 3a, and FFs (flip-flop) 3b, 3c, and 3d. In response to a signal from the clock supply source 3a, power control is implemented with respect to the PD 4.

The FF 3b sends out PSW control signals, and controls the ON/OFF of the PSW 2, to reduce the power consumption of the PD 4, which is the target of power control The FF 3c sends out power ON/OFF signals to the isolator 5. The FF 3d sends out clock control signals for performing clock gating with respect to the PD 4.

The PSW 2 turns ON or OFF the power supply to the PD 4 of a power-supply voltage VDD, according to PSW control signals from the PMU 3. The PD 4 is connected to a power-supply voltage VSS, and according to the power control by the PMU 3, the PD 4 is actually operated by the application of a Virtual VDD. The isolator 5 suppresses indefinite propagation by turning the power ON/OFF.

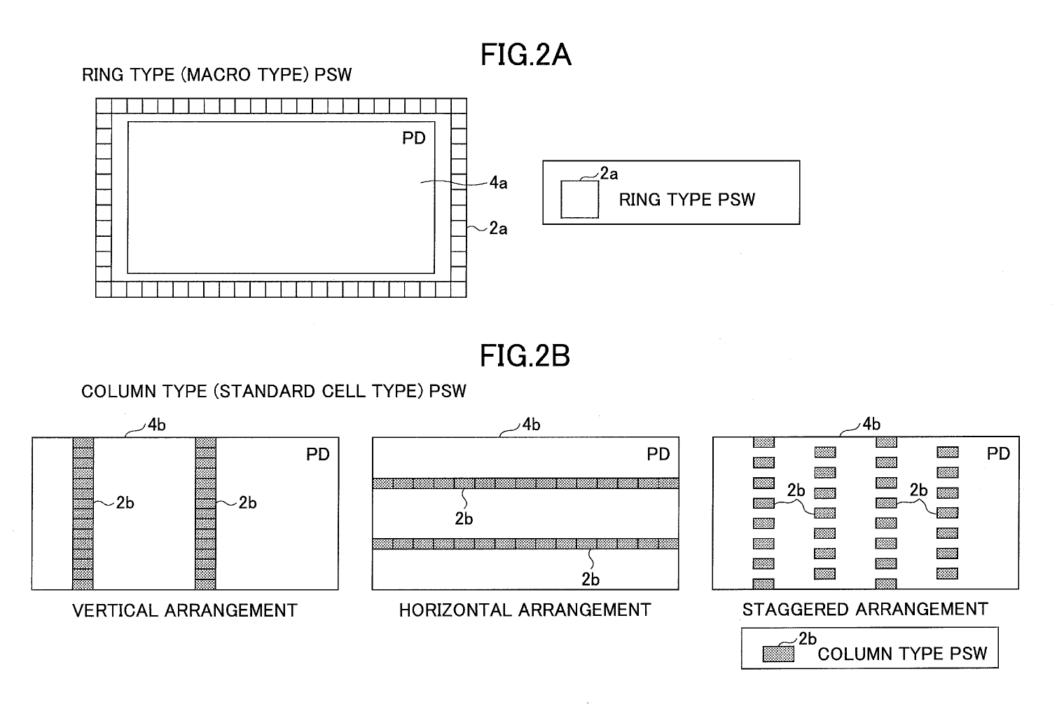

FIGS. 2A and 2B illustrate a typical arrangement example of the PSW. FIG. 2A illustrates an arrangement example of a ring type (macro type) PSW. The shape of the ring type (macro type) PSW 2a is a square (or a rectangle), and has a larger size than a column type PSW 2b illustrated in FIG. 2B. The PSWs 2a are arranged around a PD 4a.

FIG. 2B illustrates an arrangement example of a column type (standard cell type) PSW. The shape of the column type PSW 2b is rectangular. The column type PSWs 2b are mainly arranged in a vertical arrangement, a horizontal arrangement, or a staggered arrangement.

In the vertical arrangement, the long sides of the column type PSWs 2b are arranged next to each other without any gaps in each column, and the columns are arranged inside a PD 4b at predetermined intervals. In the horizontal arrangement, the short sides of the column type PSWs 2b are arranged next to each other without any gaps in the columns, and the columns are arranged inside a PD 4b at predetermined intervals. The staggered arrangement is formed by spacing part the column type PSWs 2b at predetermined intervals, in the vertical arrangement.

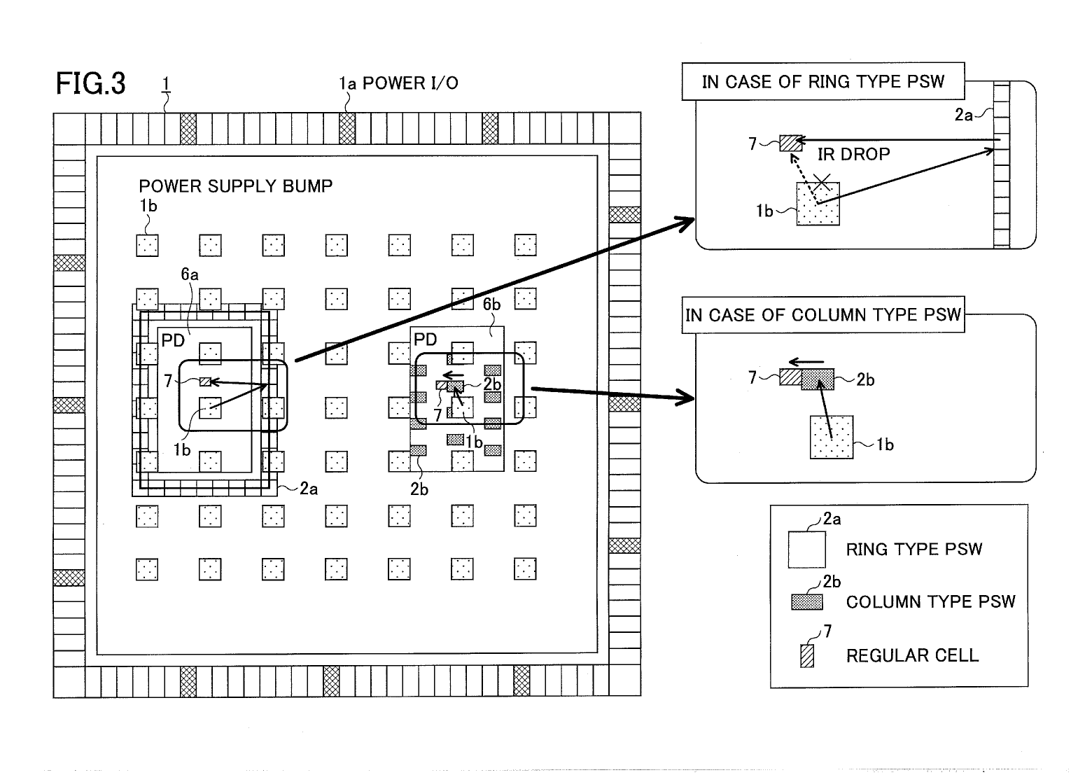

FIG. 3 is a diagram for describing the features of the ring type PSW and the column type PSW. The IR drop is described in a case where the ring type PSW and the column type PSW are arranged inside the chip 1 using an area I/O, as illustrated in FIG. 3.

A power supply bump 1b inside the chip 1 receives power supply from a power I/O 1a disposed in an area I/O.

A PD 6a is a power domain having the ring type PSWs 2a disposed along the periphery of the PD 6a. Among the ring type PSWs 2a of the PD 6a, there may be a ring type PSW 2a that receives power supply from the power supply bump 1b disposed inside. In this case, power is supplied to a regular cell 7 disposed inside the PD 6a, via the ring type PSWs 2a on the outer periphery of the PD 6a. Thus, an IR drop easily occurs.

A PD 6b is a power domain having the column type PSWs 2b disposed inside the PD 6b. The column type PSWs 2b in the PD 6b receive power supply from a power supply bump 1b disposed inside, and are capable of supplying power to the nearby regular cell 7. Therefore, the IR drop is reduced, compared to the case of the PD 6a in which ring type PSWs 2a are disposed.

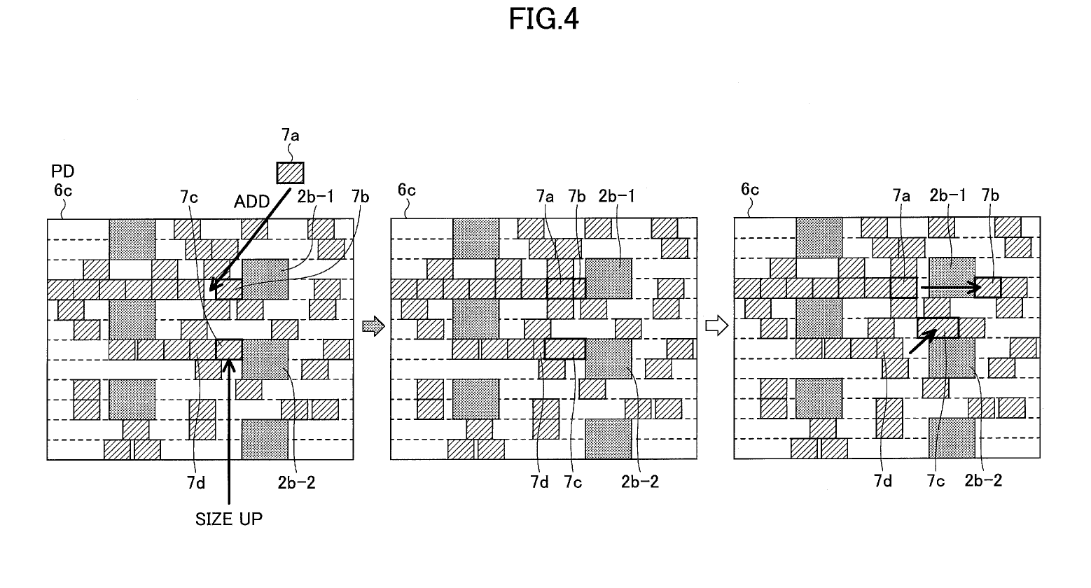

However, in the case of the column type PSW 2b, the timing convergence may be degraded. A description is given of a case where the timing convergence is degraded in the staggered arrangement. FIG. 4 illustrates an example where the timing convergence is degraded. In a PD 6c of FIG. 4, the column type PSWs 2b-1 and 2b-2 are connected with the power supply wiring, and therefore it is usually not possible to move the column type PSWs 2b-1 and 2b-2 after being disposed.

When a new cell 7a is added to an area on the left side of a regular cell 7b adjacent to the column type PSW 2b-1, and this area is smaller than the size of the new cell 7a, cell overlap occurs between the regular cell 7b and the new cell 7a by adding the new cell 7a.

In order to resolve this cell overlap, the position of the regular cell 7b may be changed (cell jump) from the left side of the adjacent column type PSW 2b-1 to the other side (right side) of the adjacent column type PSW 2b-1. By such a cell jump, the timing between the new cell 7a and the regular cell 7b may be adversely affected. Thus, with respect to the timing verification after changing the position of the cell, the convergence is degraded.

Furthermore, by changing and increasing the size of a regular cell 7c disposed adjacent to and on the left side of the column type PSW 2b-2, cell overlap occurs between the regular cell 7c and a regular cell 7d adjacent to and on the left side of the regular cell 7c.

In order to resolve this cell overlap, the position of the regular cell 7c may be changed (cell jump) to a nearby vacant area, for example the top side of the column type PSW 2b-2. By such a cell jump, the timing between the regular cell 7d and the regular cell 7c whose size has been changed, may be adversely affected. Thus, with respect to the timing verification after changing the position of the cell, the convergence is degraded.

This degradation in the timing convergence becomes more significant, as the row usage ratio increases, i.e., as the number of cells with respect to a row increases. Furthermore, as the performance (clock frequency) increases, the degradation in the timing convergence becomes more significant.

The above describes an example of a staggered arrangement; however, in the case of a vertical arrangement or a horizontal arrangement, the obstacles are in blocks, and therefore a cell jump is more likely to occur. The degradation in the timing convergence is a common problem of the column type PSWs 2b.

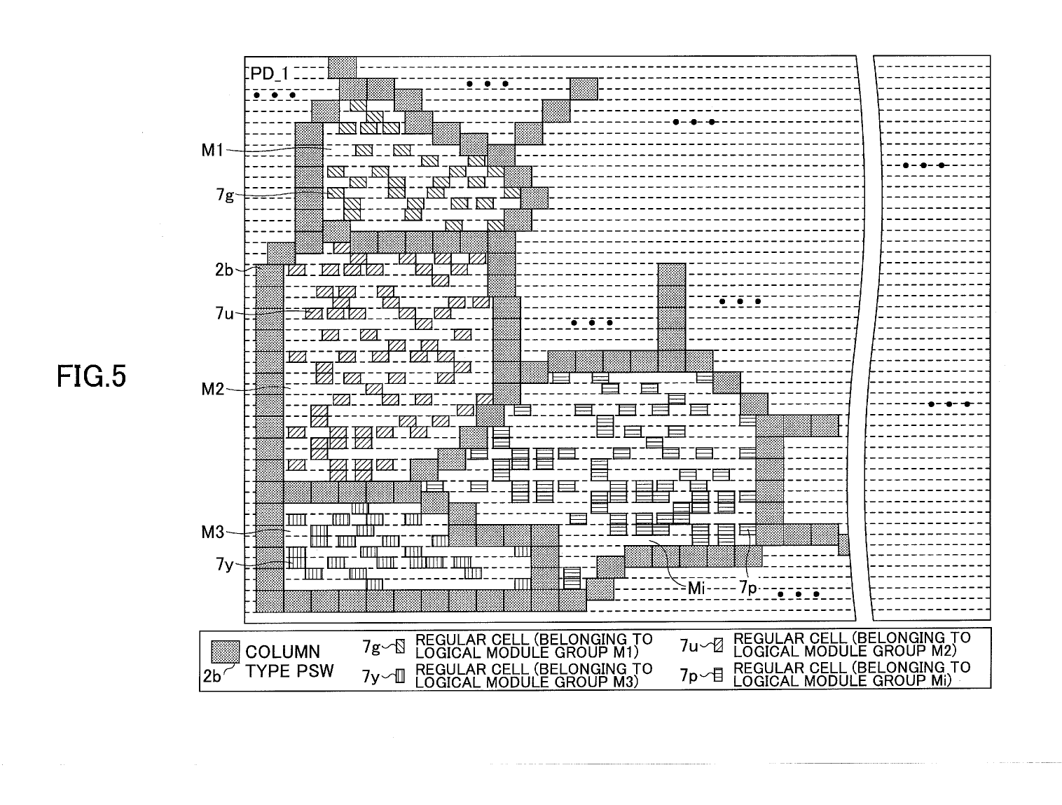

In the present embodiment, by arranging the column type PSWs as illustrated in FIG. 5, it is possible to improve the timing convergence. FIG. 5 illustrates an example of an arrangement result of the column type PSWs 2b according to the present embodiment.

FIG. 5 illustrates an example of an arrangement result of the column type PSWs 2b in one PD_1 of the chip. In the PD_1, the column type PSWs 2b (hereinafter, also simply referred to as “PSWs 2b”) are arranged so as to surround respective logical module groups, such as a plurality of regular cells 7g belonging to a logical module group M1, a plurality of regular cells 7u belonging to a logical module group M2, a plurality of regular cells 7y belonging to a logical module group M3, . . . a plurality of regular cells 7p belonging to a logical module group Mi.

That is to say, in the present embodiment, the following processes are performed.
The column type PSWs 2b are arranged around an arrangement area of cells belonging to an arbitrary logical module group.
An arrangement region is set so as to surround the arrangement area of an arbitrary logical module.

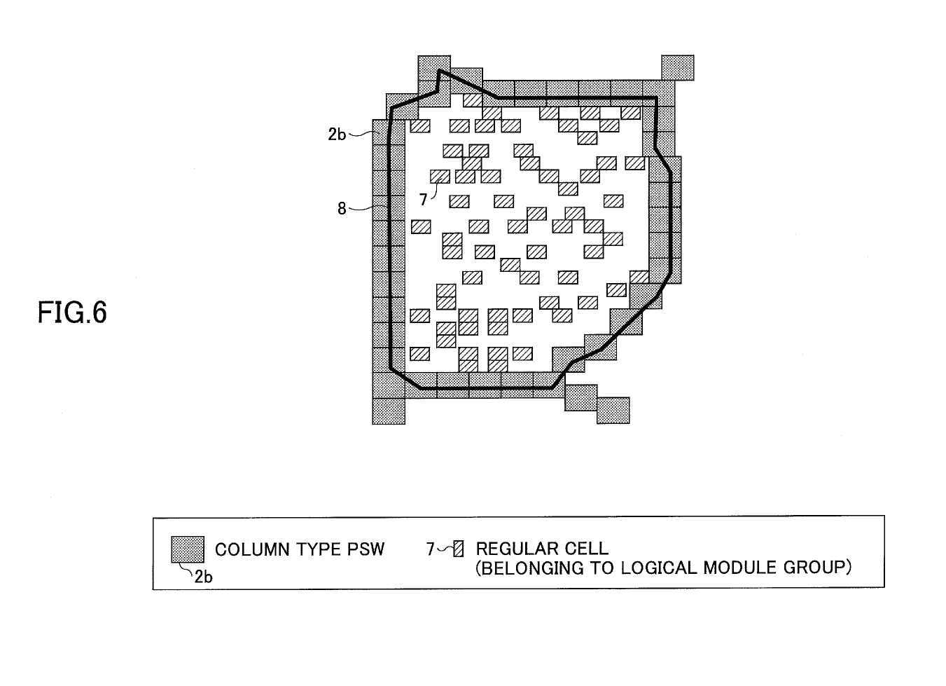

FIG. 6 illustrates an example of an arrangement region. As illustrated in FIG. 6, in the present embodiment, an arrangement region 8 is set, so as to surround an arrangement area of the regular cells 7 belonging to an arbitrary logical module group. The cells surrounded in the arrangement region 8 are not to be arranged outside the arrangement region 8. That is to say, it is not possible to arrange the cells inside a logical module group by jumping over the PSWs 2b.

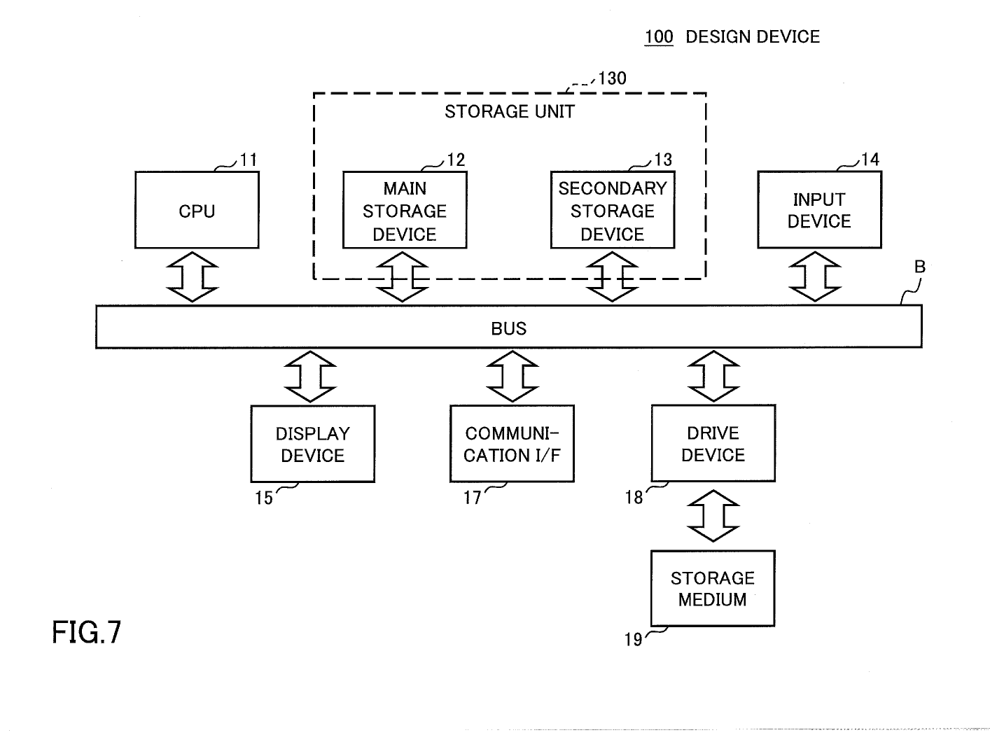

A design device according to the present embodiment has a hardware configuration as illustrated in FIG. 7. FIG. 7 illustrates a hardware configuration of a design device. As illustrated in FIG. 7, a design device 100 is a terminal controlled by a computer, and includes a CPU (Central Processing Unit) 11, a main storage device 12, a secondary storage device 13, an input device 14, a display device 15, a communication I/F (interface) 17, and a drive device 18, which are connected to a bus B.

The CPU 11 controls the design device 100 according to programs stored in the main storage device 12. As the main storage device 12, a RAM (Random Access Memory) or a ROM (Read-Only Memory) is used, and the main storage device 12 stores programs executed by the CPU 11, data needed for processes by the CPU 11, and data obtained by processes by the CPU 11. Furthermore, one area of the main storage device 12 is assigned as a work area used for processes by the CPU 11.

As the secondary storage device 13, a hard disk drive is used, and the secondary storage device 13 stores data such as programs for executing various processes. As some of the programs stored in the secondary storage device 13 are loaded into the main storage device 12 and executed by the CPU 11, various processes are realized. A storage unit 130 includes the main storage device 12 and/or the secondary storage device 13.

The input device 14 includes a mouse and a keyboard, and is used by the user for inputting various kinds of information needed for processes performed by the design device 100. The display device 15 displays various kinds of information that are needed, according to control by the CPU 11. The communication I/F 17 is connected to, for example, the Internet or a LAN (Local Area Network), and is a device for implementing control of communication with an external device. Communication by the communication I/F 17 is not limited to wireless or wired communication.

Programs for realizing processes performed by the design device 100 are provided to the design device 100 by, for example, a storage medium 19 such as a CD-ROM (Compact Disc Read-Only Memory).

The drive device 18 acts as an interface between the storage medium 19 (for example, a CD-ROM) set in the drive device 18 and the design device 100.

Furthermore, the programs for realizing various processes according to the present embodiment described below are stored in the storage medium 19, and the programs stored in the storage medium 19 are installed in the design device 100 via the drive device 18. The installed programs are executable by the design device 100.

Note that the medium for storing programs is not limited to a CD-ROM; any medium readable by a computer may be used. As a computer readable storage medium, a DVD disk, a portable recording medium such as a USB memory, and a semiconductor memory such as a flash memory may be used, other than a CD-ROM.

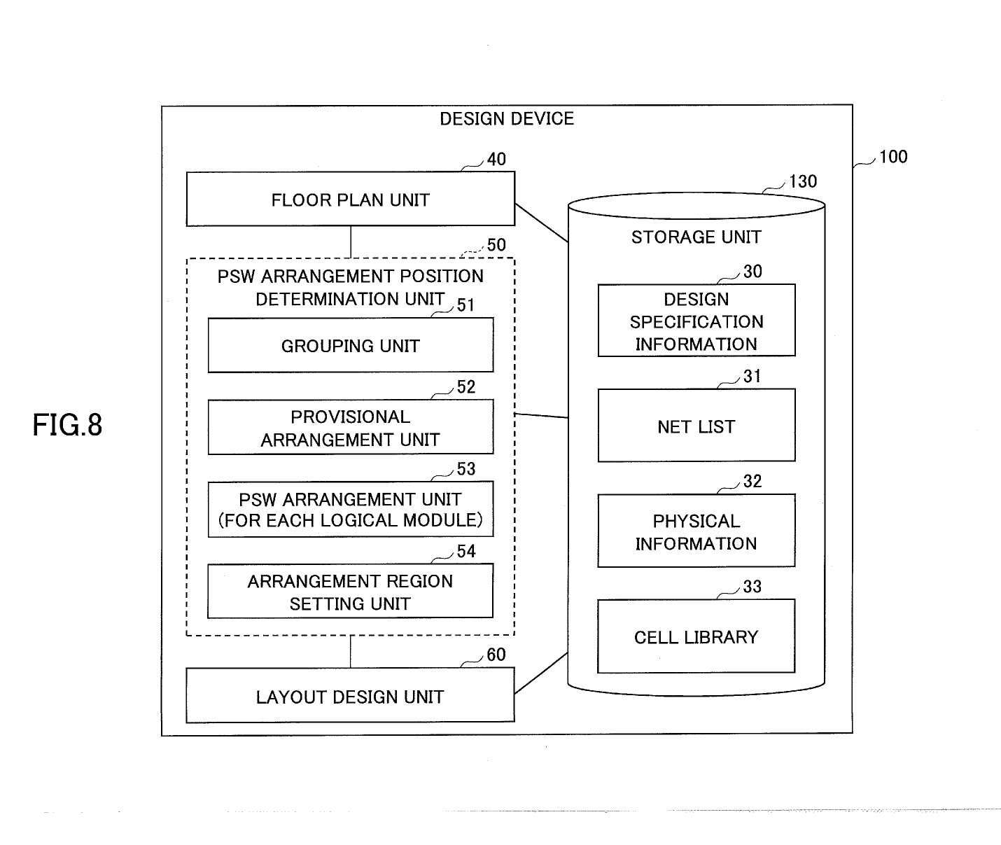

FIG. 8 illustrates an example of a functional configuration of the design device 100. As illustrated in FIG. 8, the design device 100 mainly includes a floor plan unit 40, a PSW arrangement position determination unit 50, and a layout design unit 60. The floor plan unit 40, the PSW arrangement position determination unit 50, and the layout design unit 60 are realized by processes performed as the CPU 11 executes corresponding programs. Furthermore, the storage unit 130 includes design specification information 30, a net list 31, physical information 32, and a cell library 33.

The floor plan unit 40 determines the arrangement position of each PD including a plurality of logical modules in the chip, based on the net list 31 and the design specification information 30. The physical information 32 indicating each PD arrangement position is output to the design specification information 30. In the present embodiment, the arrangement position of the PSWs in each PD is not determined by the floor plan unit 40.

The PSW arrangement position determination unit 50 determines the arrangement position of the PSWs in each of the PDs. The PSW arrangement position determination unit 50 includes a grouping unit 51, a provisional arrangement unit 52, a PSW arrangement unit 53, and an arrangement region setting unit 54.

The grouping unit 51 groups the logical modules by referring to the design specification information 30 for each PD, based on the net list 31.

The provisional arrangement unit 52 provisionally arranges the regular cells. The provisional arrangement unit 52 secures an area having a size corresponding to the column type PSWs, and provisionally arranges the regular cells in the PD for each PD that is subjected to power control. That is to say, in the area where the column type PSWs are arranged, regular cells are not provisionally arranged. The area where the column type PSWs are arranged is secured around each logical module. Furthermore, also in the areas that are not subjected to power control in the chip, regular cells are provisionally arranged. In the physical information 32 stored in the storage unit 130, the arrangement positions of the regular cells are added.

The PSW arrangement unit 53 arranges the PSWs in the area secured around the logical module for each logical module with respect to each PD. In the physical information 32, the arrangement positions of the PSWs are added.

The arrangement region setting unit 54 refers to the physical information 32 and sets an arrangement region indicating the boundary where the regular cells are arranged, based on the PSW coordinates indicating the arrangement positions of the PSWs around the logical module group. In the physical information 32, a group of coordinates indicating the arrangement region is added for each arrangement region.

The layout design unit 60 uses the net list 31 and the physical information 32 to perform layout design.

After a process by the floor plan unit 40, the PSW arrangement position determination unit 50 according to the present embodiment performs a process, and therefore at the layout design unit 60, the arrangements of regular cells are set according to the arrangement region, and therefore regular cells are not arranged over the arrangement region, i.e., regular cells are not arranged by jumping over the PSWs. Therefore, the convergence is improved with respect to the timing verification performed after laying out the chip, compared to the case where a floor plan unit 40, to which the present embodiment is not applied, arranges the PSWs by a predetermined arrangement method and then provisionally arranges regular cells.

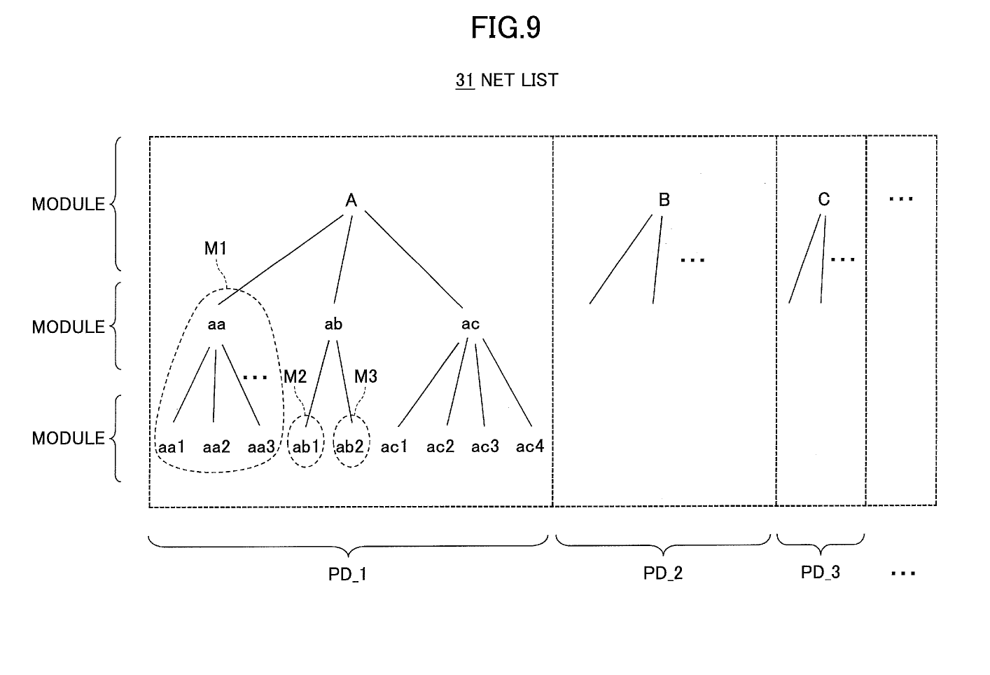

The design specification information 30 indicates design specification of the chip that is developed. The net list 31 includes connection information between cells. Furthermore, the net list 31 includes information indicating the logical modules in a hierarchical structure (FIG. 9). The physical information 32 stores coordinates of the arrangement positions of PDs, the arrangement positions of regular cells, the arrangement positions of PSWs, and the arrangement position of an arrangement region. The cell library 33 stores information of a plurality of types of cells including column type PSWs 2b, as a library.

A description is given of a configuration example of the net list 31 to which the PSW arrangement position determination unit 50 refers, with reference to FIG. 9. FIG. 9 illustrates a configuration example of the net list 31. In FIG. 9, the logical modules A, B, C, . . . , aa, ab, ac, . . . , aa1, aa2, aa3, . . . are indicated in a hierarchical structure in the net list 31.

In this example, the logical modules A, B, C of the topmost level correspond to PD_1, PD_2, and PD_3; the net list 31 includes information of logical modules other than these logical modules, for which power control is not performed, i.e., logical modules for which the power is constantly switched ON.

For each logical module, logical modules constituting the logical module are indicated. For example, the logical module A of the topmost layer includes logical modules aa, ab, ac, . . . . Furthermore, the logical module aa includes logical modules aa1, aa2, aa3, . . . .

For example, the grouping unit 51 classifies the logical module aa into a module group M1. That is to say, the logical modules aa1, aa2, aa3, . . . included in the logical module aa are classified into the same logical module group M1.

The logical module ab1 is classified into a logical module group M2. That is to say, only the logical module ab1 is classified into the logical module group M2. Furthermore, only the logical module ab2 is classified into the logical module group M3.

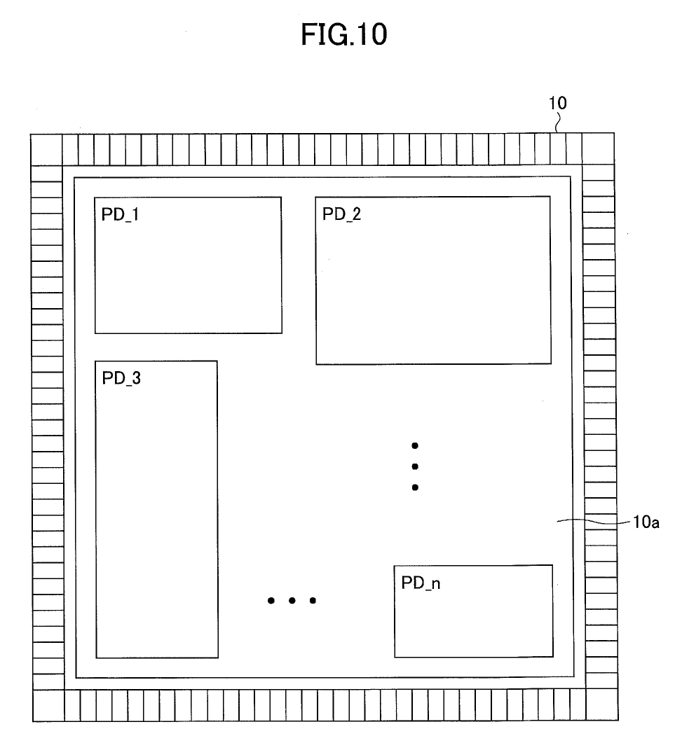

In the following, a description is given of the processes performed by the design device 100. First, a description is given of a process of determining the arrangement position of the PD performed by the floor plan unit 40, with reference to FIG. 10. FIG. 10 illustrates an example of a process of determining the arrangement positions of power domains performed by the floor plan unit 40.

As illustrated in FIG. 10, the floor plan unit 40 refers to the net list 31, and determines the arrangement positions of PD_1, PD_2, PD_3, . . . PD_n (hereinafter, collectively referred to as “PD”) in a cell arrangement area 10a in a chip 10 using an area I/O. The logical modules arranged in the power domain area are set in the design specification information 30.

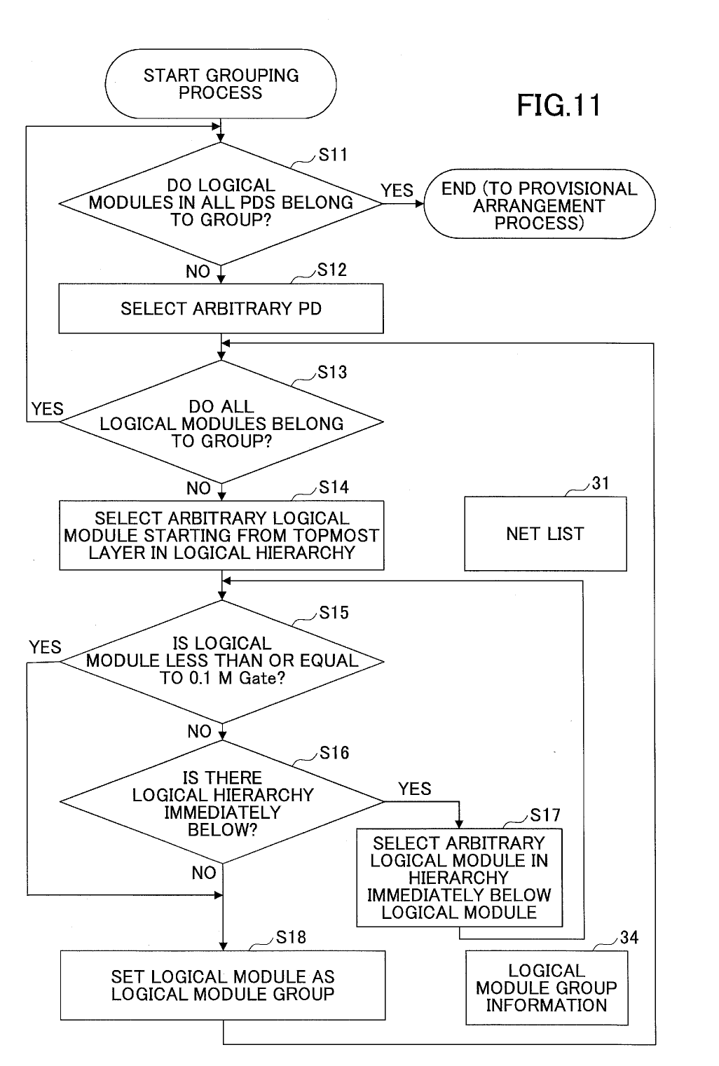

Next, a description is given of a grouping process performed by the grouping unit 51, with reference to FIG. 11. FIG. 11 is a flowchart of a grouping process. In FIG. 11, the grouping unit 51 determines whether the logical modules in all of the PDs belong to a group (step S11).

When the logical modules in all of the PDs belong to a group (YES in step S11), the grouping unit 51 ends this grouping process. Next, the provisional arrangement unit 52 performs a provisional arrangement process.

Meanwhile, when the logical modules in all of the PDs do not belong to a group (NO in step S11), the grouping unit 51 selects an arbitrary PD (step S12).

Then, the grouping unit 51 determines whether all of the logical modules belong to a group (step S13). When all of the logical modules belong to a group (YES in step S13), the grouping unit 51 returns to step S11, and executes the same process as described above.

When all of the logical modules do not belong to a group (NO in step S13), the grouping unit 51 selects an arbitrary logical module starting from the topmost layer in the logical hierarchy (step S14). In the logical hierarchy, the order of selecting logical modules in the same level is arbitrary.

Then, the grouping unit 51 determines whether the selected logical module is 0.1 M Gate (step S15). When the selected logical module is less than or equal to 0.1 M Gate (YES in step S15), the grouping unit 51 sets the logical module as a logical module group (step S18), returns to step S13, and repeats the same process as described above.

Meanwhile, when the selected logical module exceeds 0.1 M Gate (NO in step S15), the grouping unit 51 determines whether there is a logical hierarchy immediately below the corresponding logical module. (step S16). When there is no logical hierarchy (NO in step S16), the grouping unit 51 sets the logical module as a logical module group (step S18), returns to step S13, and repeats the same process as described above.

In step S18, when the logical module group is determined, logical module group information 34, in which the identification information of the logical module determined as the logical module group is associated with each PD, is stored in the storage unit 130.

Meanwhile, when there is a logical hierarchy (YES in step S16), the grouping unit 51 selects an arbitrary logical module in the logical hierarchy immediately below the logical module (step S17). In the logical hierarchy, the order of selecting logical modules in the same level is arbitrary. Then, the grouping unit 51 returns to step S15, and repeats the same process as described above.

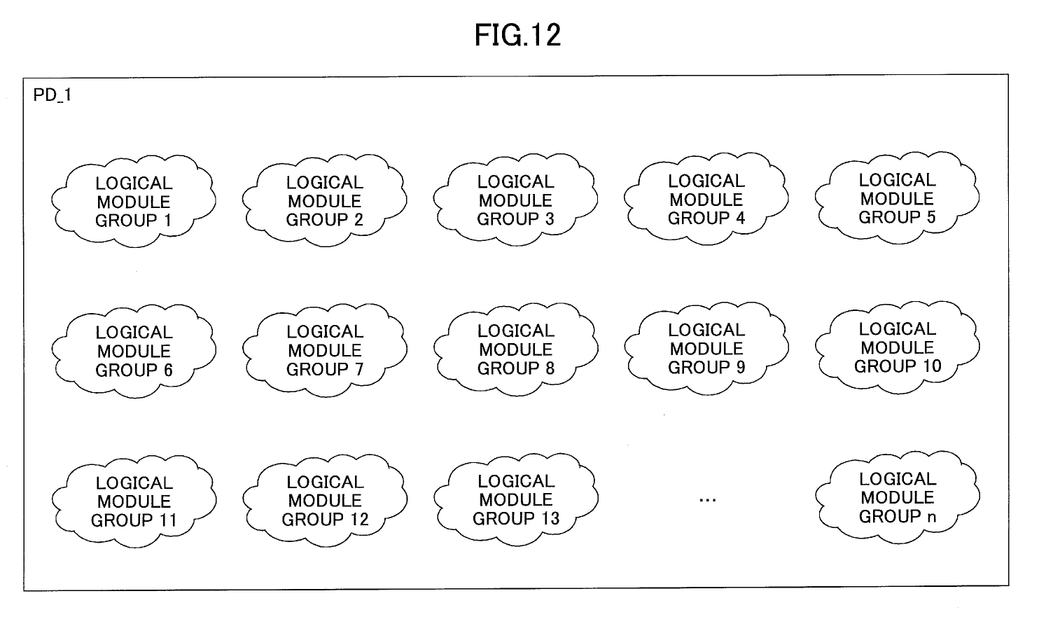

FIG. 12 schematically illustrates an example of a result of the grouping process. FIG. 12 illustrates an example of a result of the grouping process of PD_1. All of the logical modules arranged in the PD_1 are grouped into logical module groups 1, 2, 3, . . . n.

Generally, a power domain has a circuit scale of approximately 5 M Gates through 10 M Gates, and therefore by the above grouping process, approximately 50 through 100 logical module groups are formed.

In the above grouping process, the logical modules are grouped by a 0.1 M Gate scale; however, this value may be changed according to the design and technology. Furthermore, in a program corresponding to the grouping process, this value may be a variable set by the user. In the case of a 28 nm design, a 0.1 M Gate scale is an appropriate value as an embodiment.

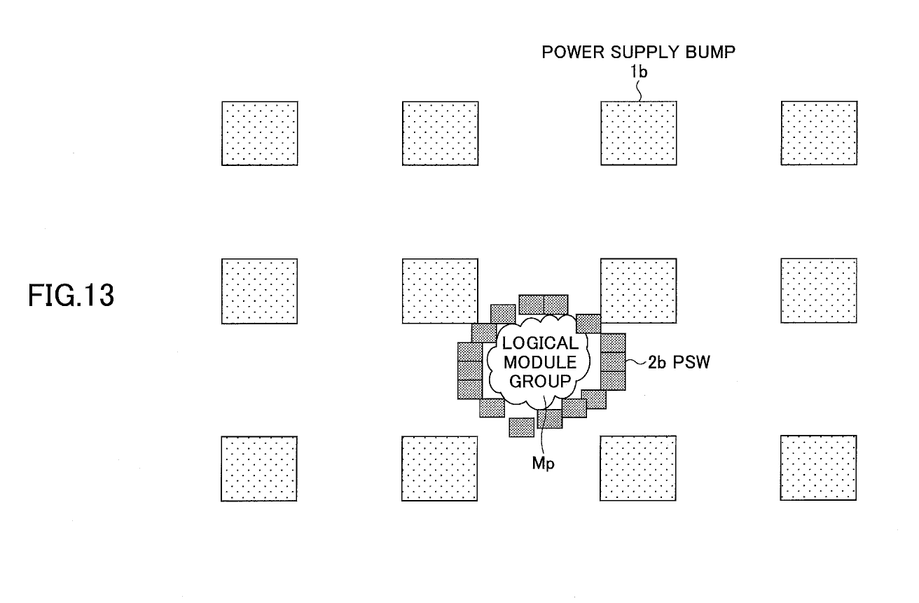

FIG. 13 is for describing the relationship between the arrangement intervals of power supply bumps and the arrangement area of a logical module group. As illustrated in FIG. 13, by making adjustments such that the arrangement intervals of power supply bumps 1b and the arrangement area of the logical module group Mp become the same, an optimum embodiment is attained in terms of reducing the IR drop. The PSW 2b is arranged near the power supply bump 1b, and therefore the IR drop is reduced.

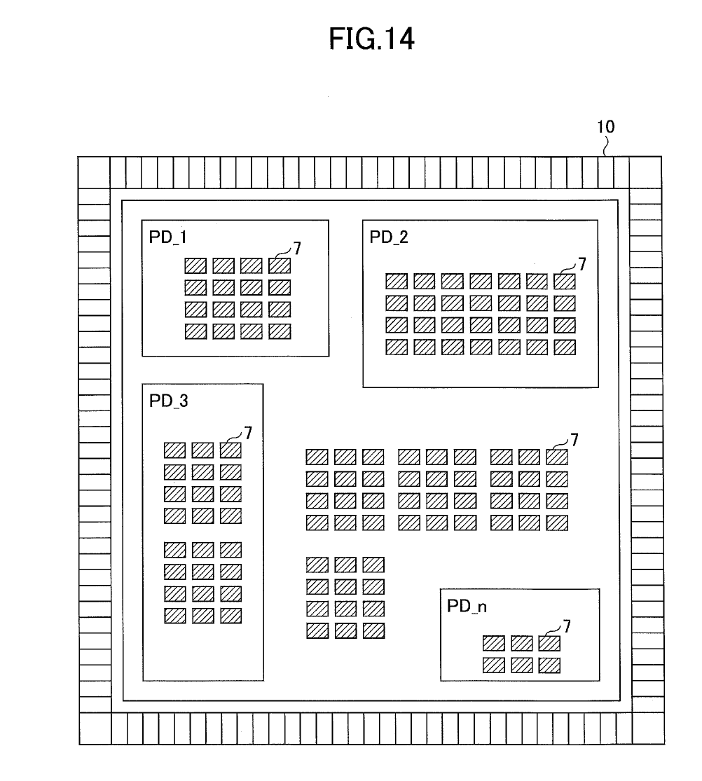

Next, a description is given of a provisional arrangement process performed by the provisional arrangement unit 52. FIG. 14 is for describing a provisional arrangement process. In FIG. 14, in the provisional arrangement process performed by the provisional arrangement unit 52, a known technology is used. A cell arrangement command is used to perform the cell arrangement of the entire chip.

As a result, the regular cells 7 are arranged in PD_1 through PD_n that are subjected to power control and in areas other than the PD_1 through PD_n to which power is constantly supplied, on the chip. The arrangement positions of the regular cells 7 are stored in the physical information 32.

In the provisional arrangement process, the regular cells 7 are preferably arranged in consideration of the following processes.

(1) In each logical module group grouped by the grouping unit 51, the regular cells 7 are collectively arranged such that the regular cells 7 are not discretely arranged.
(2) When collectively arranging the regular cells 7 in each logical module group, an area corresponding to the size of the column type PSW 2b to be used, is secured around the arrangement area of the logical module group. Furthermore, considering that the arrangement area of the regular cells 7 will increase by optimization, it is even more preferable to provide a margin in the area secured for arranging the PSWs 2b.

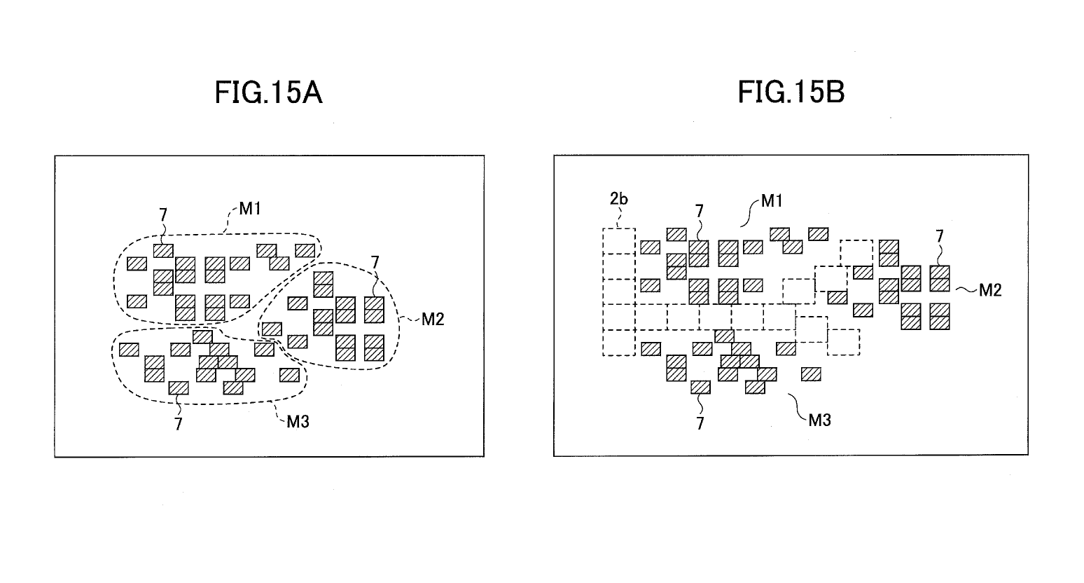

A description is given of an example of a result of the provisional arrangement process by the provisional arrangement unit 52. FIGS. 15A and 15B are for describing an example of a result of the provisional arrangement process.

FIG. 15A illustrates a case where the regular cells 7 are arranged without considering the above process (2). In this example, the regular cells 7 are collectively arranged in the corresponding logical module groups M1, M2, and M3; however, there is not enough space between the logical module groups for arranging the PSWs 2b. It is not possible to arrange the PSWs 2b around each of the logical module groups M1, M2, and M3.

Meanwhile, FIG. 15B illustrates a case according to the present embodiment, where the regular cells 7 are arranged in consideration of the above processes (1) and (2). In this example, the regular cells 7 are collectively arranged in the corresponding logical module groups M1, M2, and M3, and there is enough space for arranging the PSWs 2b between the logical module groups. Therefore, it is possible to arrange the PSWs 2b around the corresponding logical module groups M1, M2, and M3.

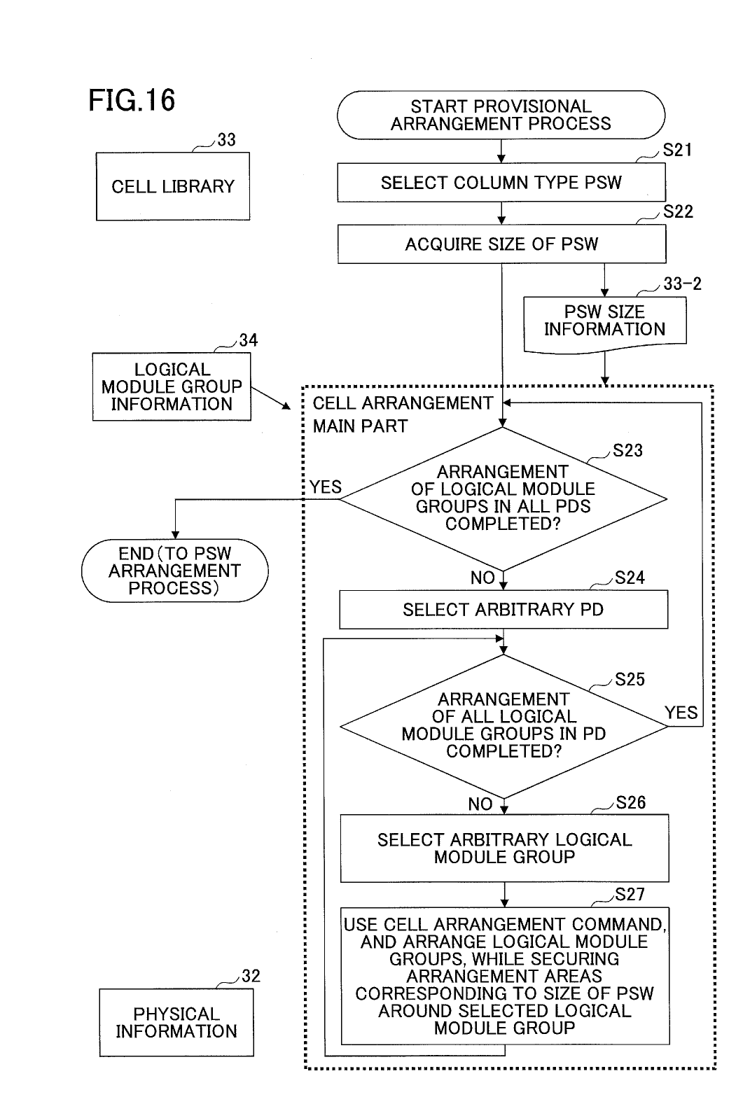

FIG. 16 is a flowchart of a provisional arrangement process. In FIG. 16, the provisional arrangement unit 52 selects the column type PSW 2b from the cell library 33 based on the design specification information 30 (step S21), and acquires the size of the PSW 2b (step S22). PSW size information 33-2 indicating the size of the selected PSW 2b is stored in the storage unit 130.

Steps S23 through S27 correspond to the process of the cell arrangement main part of the provisional arrangement unit 52.

The provisional arrangement unit 52 determines whether the arrangement of logical module groups in all PDs has been completed (step S23). When the arrangement of logical module groups in all PDs has been completed (YES in step S23), the provisional arrangement unit 52 ends the provisional arrangement process. Then, a PSW arrangement process is executed by the PSW arrangement unit 53.

Meanwhile, when the arrangement of logical module groups in all PDs has not been completed (NO in step S23), the provisional arrangement unit 52 selects an arbitrary PD from the logical module group information 34 (step S24), and determines whether the arrangement of all logical module groups in the PD has been completed (step S25).

When the arrangement of all logical module groups in the PD has been completed (YES in step S25), the provisional arrangement unit 52 returns to step S23, and repeats the same process as described above. Meanwhile, when the arrangement of all logical module groups in the PD has not been completed (NO in step S25), the provisional arrangement unit 52 selects an arbitrary logical module group from the logical module group information 34 (step S26).

Then, the provisional arrangement unit 52 uses a cell arrangement command (known technology), and arranges the logical module groups, while securing arrangement areas corresponding to the size of the PSW indicated by the PSW size information 33-2, around the selected logical module group (step S27). The regular cells 7 belonging to the logical module group are arranged in the chip 10. The arrangement positions of the regular cells 7 are stored in the physical information 32. Subsequently, the provisional arrangement unit 52 returns to step S25, and repeats the same process as described above.

The completion of the process with respect to a PD may be confirmed by providing a PD flag corresponding to identification information of each PD. Similarly, the completion of the process with respect to a logical module group may be confirmed by providing a LMG flag corresponding to identification information of each logical module group. A value “1” is to be set for the PD flag or the LMG flag when the process is completed. The same applies to the following processes.

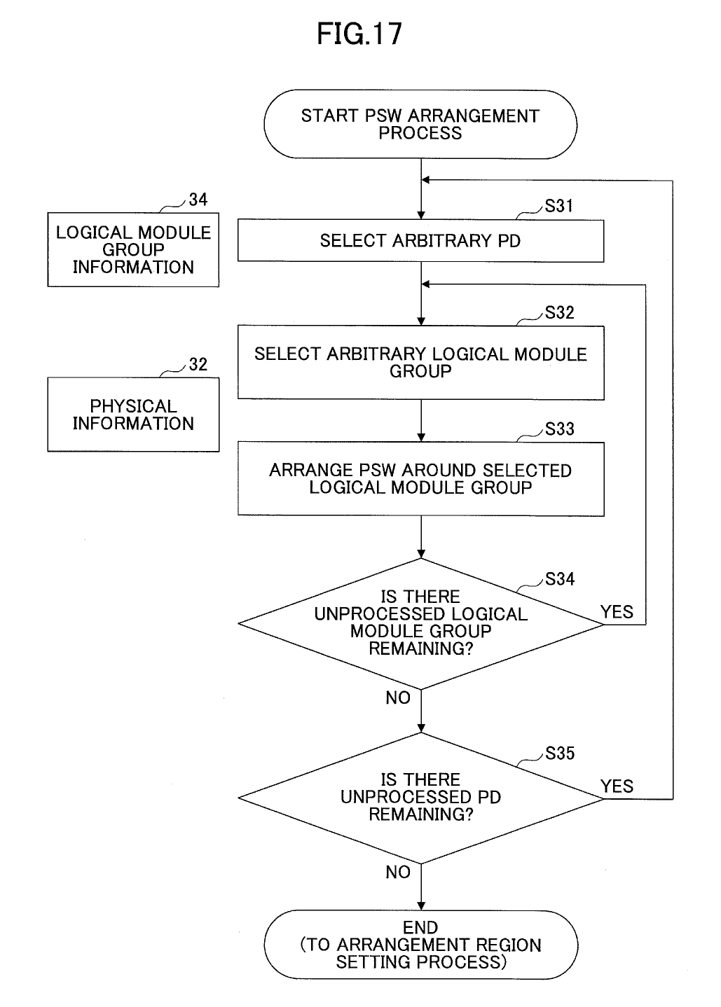

A description is given of a PSW arrangement process by the PSW arrangement unit 53 with reference to FIG. 17. FIG. 17 is a flowchart of a PSW arrangement process. In FIG. 17, the PSW arrangement unit 53 selects an arbitrary PD from the logical module group information 34 (step S31), and further selects an arbitrary logical module group in the selected PD (step S32).

The PSW arrangement unit 53 arranges the PSWs 2b around the selected logical module group (step S33). The arrangement positions of the PSWs 2b are stored in the physical information 32.

Then, the PSW arrangement unit 53 determines whether there are any unprocessed logical module groups remaining (step S34). When there is a remaining logical module group (YES in step S34), the PSW arrangement unit 53 returns to step S32, and repeats the same process as described above.

Meanwhile, when there are no remaining logical module groups (NO in step S34), the PSW arrangement unit 53 determines whether there are any unprocessed PDs remaining (step S35). When there is an unprocessed PD remaining (YES in step S35), the PSW arrangement unit 53 returns to step S31, and repeats the same process as described above. Meanwhile, when there are no unprocessed PDs remaining (NO in step S35), the PSW arrangement unit 53 ends the PSW arrangement process. Then, an arrangement region setting process is executed by the arrangement region setting unit 54.

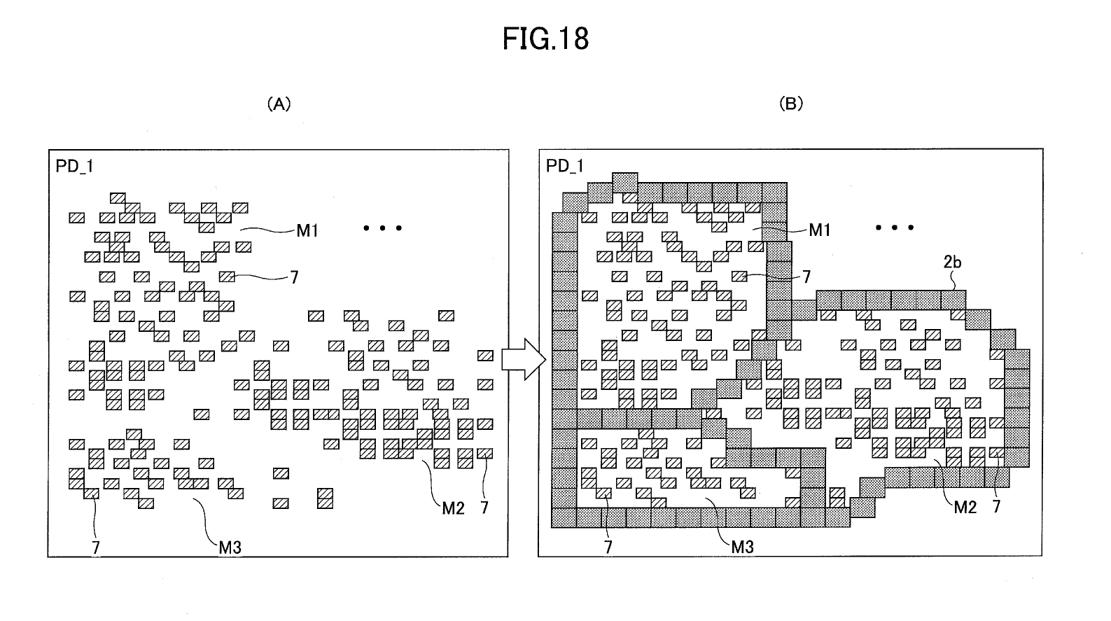

Next, a description is given of an example of a PSW arrangement process performed by the PSW arrangement unit 53. FIG. 18 illustrates an example of a PSW arrangement process performed by the PSW arrangement unit 53. FIG. 18(A) illustrates an example of a result of a provisional arrangement process performed with respect to PD_1. In this state, only the regular cells 7 have been provisionally arranged, and the PSWs 2b are not arranged. Thus, in the physical information 32, only the arrangement positions of PD_1, PD_2, PD_3, . . . and the arrangement positions of the regular cells 7 are stored.

FIG. 18(B) illustrates an example of a result of a PSW arrangement process performed with respect to PD_1. As the PSW arrangement process has been executed, PSWs 2b are arranged around each of the logical module groups M1, M2, M3, . . . . Here, the arrangement positions of the PSWs are additionally stored in the physical information 32.

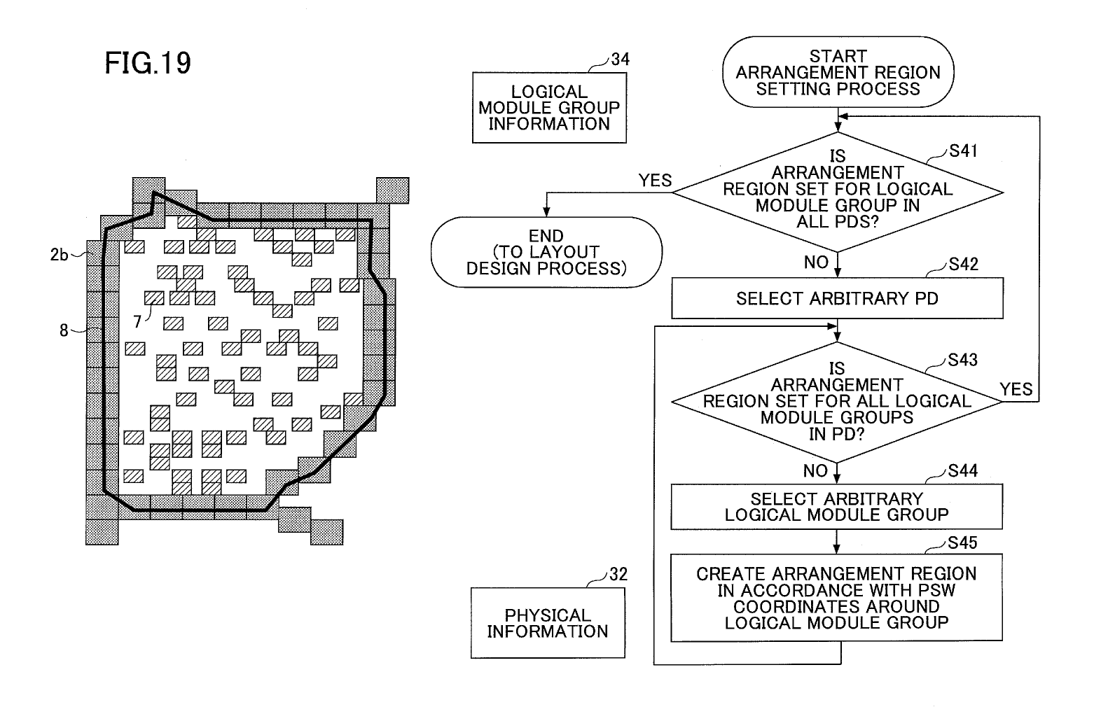

Next, a description is given of an arrangement region setting process performed by the arrangement region setting unit 54. FIG. 19 is a flowchart of an arrangement region setting process. In FIG. 19, the arrangement region setting unit 54 refers to the logical module group information 34, and determines whether arrangement regions are set for the logical module groups in all the PDs (step S41).

The arrangement region setting unit 54 selects an arbitrary PD from the logical module group information 34 (step S42), and determines whether an arrangement region is set in all of the logical module groups in the PD (step S43). When an arrangement region is set (YES in step S43), the arrangement region setting unit 54 returns to step S41, and repeats the same process as described above.

Meanwhile, when an arrangement region is not set (NO in step S43), the arrangement region setting unit 54 selects an arbitrary logical module group from the logical module group information 34 (step S44).

Then, the arrangement region setting unit 54 creates an arrangement region in accordance with PSW coordinates indicating the arrangement positions of the PSWs around the logical module group (step S45), and returns to step S43 and repeats the same process as described above. In the physical information 32, a group of coordinates expressing the arrangement region is stored.

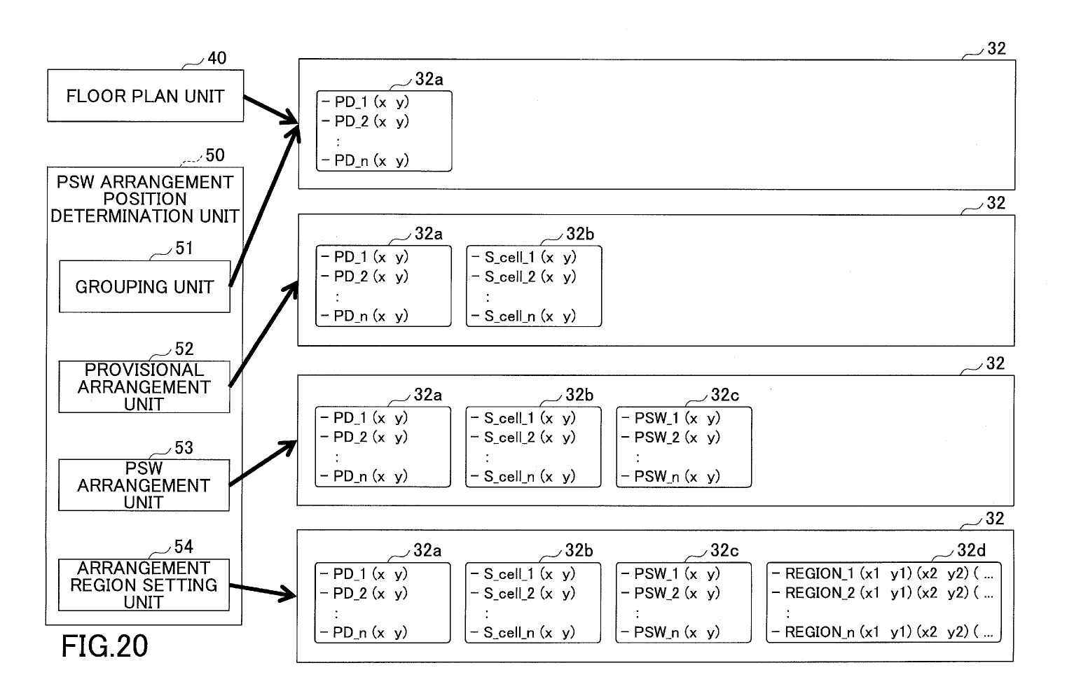

Next, a description is given of an example of data stored in the physical information 32 according to the present embodiment. FIG. 20 illustrates an example of data stored in the physical information 32. As illustrated in FIG. 20, PD arrangement position information 32a indicating the arrangement position of each of the power domains by coordinates, is stored in the physical information 32 by the floor plan unit 40. In the PD arrangement position information 32a, coordinates of the arrangement positions are stored in association with the respective identification information items of the power domains PD_1, PD_2, . . . , PD_n.

Furthermore, group information indicating the logical modules that have been grouped for each of the PDs is added to the PD arrangement position information 32a of the physical information 32, by the grouping unit 51. In the example of FIG. 9, identification information aa of a logical module is associated with PD_1, identification information ab1 of a logical module is associated with PD_2, and identification information ab2 of a logical module is associated with PD_3.

Regular cell arrangement position information 32b indicating the coordinates of the arrangement positions of the regular cells 7, is stored in the physical information 32 by the provisional arrangement unit 52. In the regular cell arrangement position information 32b, coordinates of arrangement positions are stored in association with the respective identification information items of the regular cells 7, S_cell_1, S_cell_2, . . . , S_cell_n.

PSW arrangement position information 32c indicating the coordinates the arrangement positions of the PSWs 2b is stored in the physical information 32 by the PSW arrangement unit 53. In the PSW arrangement position information 32c, coordinates of arrangement positions are stored in association with the respective identification information items of the PSW 2b, PSW_1, PSW_2, . . . , PSW_n.

Arrangement region arrangement position information 32d indicating the coordinates the arrangement positions of the arrangement regions 8 is stored in the physical information 32 by the arrangement region setting unit 54. In the arrangement region arrangement position information 32d, coordinates of arrangement positions are stored in association with the respective identification information items of the arrangement regions 8, REGION_1, REGION_2, . . . , REGION_n.

As described above, in LSI design using the column type PSW 2b, the logical modules are grouped in the respective power domains and the regular cells 7 are provisionally arranged, and subsequently the PSWs 2b are arranged around the logical module groups, and therefore the timing convergence is improved.

The present invention is not limited to the specific embodiments described herein, and variations and modifications may be made without departing from the spirit and scope of the present invention.

According to an aspect of the embodiments, the timing convergence is improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A design method executed by a computer, the design method comprising:
grouping logical modules in each of power domains arranged on a chip;
provisionally arranging regular cells in each of logical module groups formed by the grouping; and
arranging power switches around each of the logical module groups.

2. The design method according to claim 1, further comprising:
creating arrangement regions based on arrangement positions of the power switches arranged around each of the logical module groups.

3. The design method according to claim 2, further comprising:
implementing a floor plan of arranging the power domains on the chip, wherein
the power switches are not arranged in the floor plan.

4. The design method according to claim 3, wherein
the grouping includes grouping the logical modules based on a group size that is a reference of the grouping.

5. The design method according to claim 4, wherein
the provisionally arranging of the regular cells includes storing arrangement positions of the regular cells in physical information stored in a storage unit, the physical information including arrangement positions of the power domains arranged by the floor plan,
the arranging of the power switches includes storing, in the physical information, the arrangement positions of the power switches arranged around each of the logical module groups, and
the creating of the arrangement regions includes storing, in the physical information, arrangement positions of the arrangement regions.

6. A non-transitory computer-readable recording medium storing a design program that causes a computer to execute a process comprising:
grouping logical modules in each of power domains arranged on a chip;
provisionally arranging regular cells in each of logical module groups formed by the grouping; and
arranging power switches around each of the logical module groups.

7. The non-transitory computer-readable recording medium according to claim 6, the process further comprising:
creating arrangement regions based on arrangement positions of the power switches arranged around each of the logical module groups.

8. The non-transitory computer-readable recording medium according to claim 7, the process further comprising:
implementing a floor plan of arranging the power domains on the chip, wherein
the power switches are not arranged in the floor plan.

9. The non-transitory computer-readable recording medium according to claim 8, wherein
the grouping includes grouping the logical modules based on a group size that is a reference of the grouping.

10. The non-transitory computer-readable recording medium according to claim 9, wherein
the provisionally arranging of the regular cells includes storing arrangement positions of the regular cells in physical information stored in a storage unit, the physical information including arrangement positions of the power domains arranged by the floor plan,
the arranging of the power switches includes storing, in the physical information, the arrangement positions of the power switches arranged around each of the logical module groups, and
the creating of the arrangement regions includes storing, in the physical information, arrangement positions of the arrangement regions.

11. A design device comprising:
a processor programmed to execute a process including
grouping logical modules in each of power domains arranged on a chip,
provisionally arranging regular cells in each of logical module groups formed by the grouping, and
arranging power switches around each of the logical module groups.

12. The design device according to claim 11, the process further including
creating arrangement regions based on arrangement positions of the power switches arranged around each of the logical module groups.

13. The design device according to claim 12, the process further including
implementing a floor plan of arranging the power domains on the chip, wherein
the power switches are not arranged in the floor plan.

14. The design device according to claim 13, wherein
the grouping includes grouping the logical modules based on a group size that is a reference of the grouping.

15. The design device according to claim 14, wherein
the provisionally arranging of the regular cells includes storing arrangement positions of the regular cells in physical information stored in a storage unit, the physical information including arrangement positions of the power domains arranged by the floor plan,
the arranging of the power switches includes storing, in the physical information, the arrangement positions of the power switches arranged around each of the logical module groups, and
the creating of the arrangement regions includes storing, in the physical information, arrangement positions of the arrangement regions.

16. A device comprising:
a power domain, wherein
regular cells arranged in the power domain are grouped, and power switches are arranged around each of the groups.
